(19) United States
(12) Patent Application Publication
(10) Pub. No.: US 2025/0224425 A1
(43) Pub. Date: Jul. 10, 2025

(54) METHOD AND SYSTEM FOR ESTIMATING VOLTAGE

(71) Applicant: Alberto BAUER, Al Menara (AE)

(72) Inventor: Alberto BAUER, Al Menara (AE)

(21) Appl. No.: 18/849,493

(22) PCT Filed: Apr. 13, 2023
(86) PCT No.: PCT/IT2023/000008

§ 371 Date: Sep. 22, 2024

(30) Foreign Application Priority Data
Apr. 15, 2022 (IT) 102022000007442

(51) Int. Cl. G01R 15/16; G01R 19/00

(52) U.S. Cl. CPC G01R 15/16; G01R 19/0084

(57) ABSTRACT

A method and a system for estimating the value of the voltage relating to an element under voltage ET. The system comprises alive element ET, a first capacitor C1.sx, a second capacitor 01.dx, a third capacitor 02.sx, a fourth capacitor 02.dx, a fifth capacitor CS.dx. The method involves the use of the electrical values obtained through this system.

### FIELD OF INVENTION

The present invention regards the sector of Methods and Systems for estimating the voltage value of a live element.

More particularly, the present invention relates to a Method and a System for estimating the voltage of a live element, in which, for example, said live element can be a conductor, or a bar, or a bushing, or other live element.

### BACKGROUND OF THE INVENTION

Methods and systems are currently known for estimating the voltage value of a live element.

Said known methods have a series of drawbacks. A first drawback is due to the fact that they do not allow a correct and/or safe estimate of the voltage value of the live element to be maintained over time, due to the aging of the electrical components and/or other reasons.

Said known systems have a series of drawbacks.

A first drawback is due to the fact that they do not allow a correct and/or safe estimate of the voltage value of the live element to be maintained over time, due to the aging of the electrical components and/or other reasons.

A second drawback is due to the fact that in order to maintain a desired measurement precision over time, these systems require maintenance which is difficult and costly.

A third drawback is due to the fact that the maintenance and/or repair operations of said systems can be carried out only if the element subject to measurement is not live.

A fourth drawback is due to the fact that the maintenance and/or repair operations of said systems can be performed only and exclusively by highly specialized workers.

### OBJECT OF THE INVENTION

The object of the present invention is therefore to solve the aforementioned drawbacks.

The invention, which is characterized by the claims, solves the problem of creating a Method for estimating the voltage value relating to a live element of a system comprising: a first capacitor comprising a respective first pole and a second pole; a second capacitor comprising a respective first pole and a second pole; a third capacitor comprising a respective first pole and a second pole; a fourth capacitor comprising a respective first pole and a second pole; a fifth capacitor comprising a respective first pole and a second pole; wherein said first capacitor has its first pole connected to said live element; wherein said second capacitor has its first pole connected to said live element; wherein said third capacitor has its first pole connected to the second pole of the first capacitor and its second pole connected to ground; wherein said fourth capacitor has its first pole connected to the second pole of the second capacitor and its second pole connected to the first pole of the fifth capacitor; wherein said fifth capacitor has its second pole connected to ground; wherein said first capacitor and said second capacitor are two equal and/or identical capacitors; wherein said third capacitor, said fourth capacitor and said fifth capacitor are three identical and/or identical capacitors; wherein said first capacitor supplies on its second pole and/or along the respective conducting wire which connects it to the third capacitor a voltage value defined herein as first voltage value; wherein said fourth capacitor supplies on its second pole and/or along the respective conducting wire which connects it to the fifth capacitor, a voltage value defined herein as fourth voltage value; and characterized in that said method for estimating the voltage value of the element under voltage comprises the following operations: 1) Detecting at least one voltage value relating to a first point/node positioned along the conducting wire which connects the first capacitor to the third capacitor; 2) Detecting at least one voltage value relating to a second point/node positioned along the conducting wire that connects the fourth capacitor to the fifth capacitor; 3) Perform the aforementioned voltage estimate using the voltage value relating to the first point/node detected in the aforementioned operation 1) and the voltage value relating to the second point/node detected in the aforementioned operation 2).

The invention, which is characterized by the claims, solves the problem of creating a system for estimating the voltage value relating to a live element, characterized in that it comprises: a first capacitor comprising a respective first pole and a second pole; a second capacitor comprising a respective first pole and a second pole; a third capacitor comprising a respective first pole and a second pole; a fourth capacitor comprising a respective first pole and a second pole; a fifth capacitor comprising a respective first pole and a second pole; wherein said first capacitor has its first pole connected to said live element; wherein said second capacitor has its first pole connected to said live element; wherein said third capacitor has its first pole connected to the second pole of the first capacitor and its second pole connected to ground; wherein said fourth capacitor has its first pole connected to the second pole of the second capacitor and its second pole connected to the first pole of the fifth capacitor; wherein said fifth capacitor has its second pole connected to ground; wherein said first capacitor and said second capacitor are two equal and/or identical capacitors; wherein said third capacitor, said fourth capacitor and said fifth capacitor are three equal and/or identical capacitors; wherein said first capacitor supplies on its second pole and/or along the respective conducting wire which connects it to the third capacitor a voltage value defined herein as first voltage value; wherein said fourth capacitor provides to its second pole and/or along the respective conducting wire which connects it to the fifth capacitor, a voltage value defined herein as fourth voltage value.

### BRIEF DESCRIPTION OF THE DRAWINGS

Further characteristics and advantages of the present invention will be more evident from the following description of some of its preferred practical embodiments, given here by way of purely non-limiting example, made with reference to the figures of the attached drawings in which:

FIG. 1 schematically illustrates a first embodiment of the system object of the present invention;

FIG. 2 schematically illustrates a second embodiment of the system object of the present invention;

FIGS. 3, 4 and 5 illustrate waveforms of electrical voltage.

### PREFERRED EXAMPLE FORMS OF IMPLEMENTATION PRACTICES METHOD

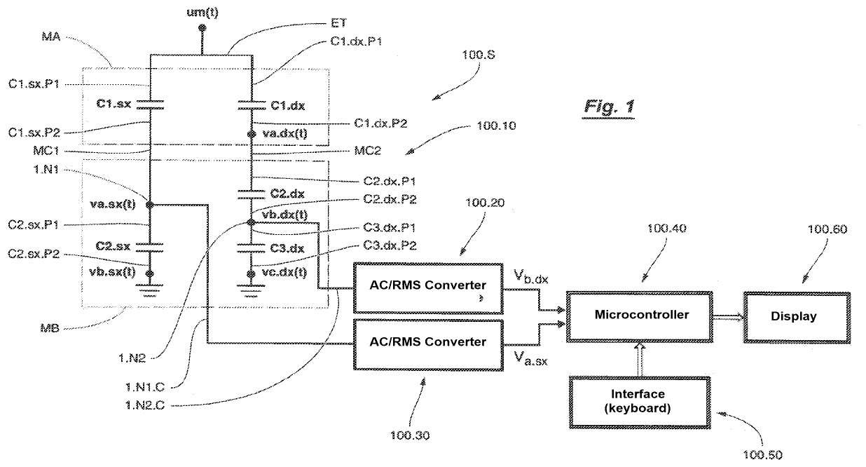

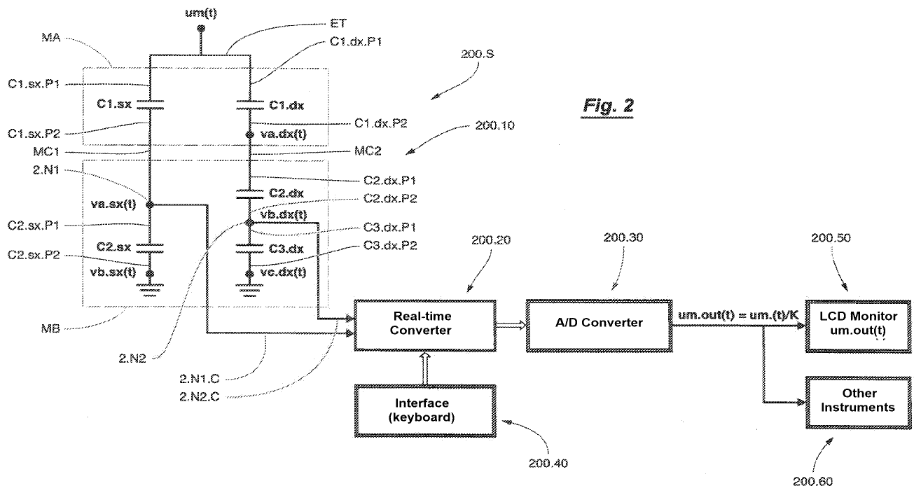

With reference to FIGS. 1 and 2, the method object of the present invention for estimating the value of the voltage relating to a live element ET uses: a first capacitor C1.sx comprising a respective first pole C1.sx.p1 and a second pole C1.Sx.p2; a second capacitor C1.dx comprising a respective first pole C2.dx.p1 and a second pole C2.dx.p2; a third capacitor C2.sx comprising a respective first pole C2.sx.p1 and a second pole C2.sx.p2; a fourth capacitor C2.dx comprising a respective first pole C2.dx.p1 and a second pole C2.dx.p2; a fifth capacitor C3.dx comprising a respective first pole C3.dx.p1 and a second pole C3.dx.p2.

The first capacitor C1.sx has its first pole C1.sx.p1 connected to said element under voltage ET and also the second capacitor C1.dx has its first pole C1.dx.p1 connected to said element under voltage ET,

The third capacitor C2.sx has its first pole C2.sx.p1 connected to the second pole C1.sx.p2 of the first capacitor C1.sx and its second pole C2.sx.p2 connected to ground.

_The fourth capacitor C2.dx has its first pole C2.dx.p1 connected to the second pole C1.dx.p2 of the second capacitor C1.dx and its second pole C2.dx.p2 connected to the first pole C3.dx.p1 of the fifth capacitor C3.dx.

The fifth capacitor C3.dx has its second pole C3.dx.p2 connected to ground. Preferably, said method uses a first capacitor C1.sx and a second capacitor C1.dx which are two equal and/or identical capacitors.

Still preferably, said method uses a third capacitor C2.sx, a fourth capacitor C2.dx and a fifth capacitor C3.dx which are three equal and/or identical capacitors.

With reference to the components as described above, the first capacitor C1.sx supplies on its second pole C1.sx.p2 and/or along the respective conducting wire C1.sx.p2_MC1_C2.sx.p1 which connects it to the third capacitor C2.sx a voltage value vasx(t) defined here as the first voltage value and, moreover, the fourth capacitor C2.dx supplies on its second pole C2.dx.p2 and/or along the respective conducting wire C2.dx.p2_C3.dx.p1 which connects it to the fifth capacitor C3.dx, a voltage value vb.dx(t) here defined as fourth voltage value.

With reference to the above described, the estimate of the voltage value of the element ET under voltage is calculated using the following values: 1) at least one voltage value detected pertaining to a first point/node 1.N1/2.N1 positioned along the conducting wire C1.sx.p2_MC1_C2.sx.p1 which connects the first capacitor C1.sx to the third capacitor (C2.sx); and 2) at least one voltage value detected relating to a second point/node 1.N2/2.N2 positioned along the conducting wire C2.dx.p2_C3.dx.p1 which connects the fourth capacitor C2.dx to the fifth capacitor C3.dx.

With reference to the method described above, preferably, after installing the components for their use in relation to voltage estimation, during the passage of time, said first capacitor C1.sx and said second capacitor C1.dx are subjected to the same operating and/or exercise and/or environmental and/or aging conditions.

According to a first exemplary embodiment of the method object of the present invention, see FIG. 1, system 300.S, the voltage value of the ET element is calculated using the following equation:

$$Um = Va . sx \cdot Vb . dx / ( Va . sx - Vb . dx ) \qquad ( equation\_ 1 )$$

where:
Um is the RMS value of the voltage relating to said element under voltage ET;
Va.sx=Effective value of the voltage relating to the second pole C1.sx.p2 of the first capacitor C1.sx and/or relating to a first node 1.N1 positioned along the conducting wire C1.sx.P2_MC1_C2.sx.p1 which connects the first capacitor C1.sx to third capacitor C2.sx;
Vb.dx=Effective value of the voltage relating to the second pole C2.dx.p2 of the fourth capacitor C2.dx and/or relating to a second node 1.N2 positioned along the conducting wire C2.dx.p2_C3.dx.p1 which connects the fourth capacitor C2.dx to fifth capacitor C3.dx.

According to a second exemplary embodiment of the method object of the present invention, see FIG. 2, system 400.S, the voltage value of the element ET is calculated using the following equation:

$$um ( t ) = va . sx ( t ) vb . dx ( t ) I ( va . sx ( t ) - vb . dx ( t ) ) \qquad ( equation\_ 2 )$$

where:
um(t) is the estimated value of the instantaneous primary voltage relating to said element under voltage ET;
va.sx(t)=Value of the instantaneous voltage relating to the second pole C1.sx.p2 of the first capacitor C1.sx and/or relating to a first node 2.N1 positioned along the conducting wire C1.sx.P2_MC1_C2.sx.p1 which connects the first capacitor C1.sx to the third capacitor C2.sx;
vb.dx(t)=Value of the instantaneous voltage relating to the second pole C2.dx.p2 of the fourth capacitor C2.dx and/or relating to a second node 2.N2 positioned along the conducting wire C2.dx.p2_C3.dx.p1 which connects the fourth capacitor C2.dx to the fifth capacitor C3.dx.

With reference to FIGS. 1 and 2, the method object of the present invention for estimating the value of the voltage relating to an element under voltage ET uses a system, 300.S/400.S, in which the system 300.S is schematically illustrated in FIG. 1 and the system 400.S is illustrated schematically in FIG. 2, in which said two systems 300.S/400.S have common elements described in the present specification with the same reference.

With reference to said method, the relative system 300.S/400.S configures a schematic electric circuit, indicated with 300.10 in FIG. 1 and with 400.10 in FIG. 2, which substantially comprises: the first capacitor C1.sx; the second capacitor C1.dx; the third capacitor C2.sx; the fourth capacitor C2.dx; the fifth capacitor C3.dx; which are mutually associated and/or connected in the manner described above.

With reference to FIG. 1, always preferably, the method object of the present invention can be implemented by means of a system 300.S which can further comprise the following components: a first ac/rms converter 300.20 connected by means of a respective conductor 1.N2.0 to the second node 1.N2 positioned along the connecting conductor C2.dx.p2_C3.dx.p1 between the fourth capacitor C2.dx and the fifth capacitor C3.dx; a second ac/rms converter 300.30 connected via a respective conductor 1.N1.0 to the first node 1.N1 positioned along the connecting conductor C1.sx.p2_MC1_C2.sx.p1 between the first capacitor C1.sx and the third capacitor C2.sx; a microcontroller 300.40; a display 300.60.

With reference to FIG. 2, always preferably, the method object of the present invention is implemented by means of a system 400.S which can further comprise the following components: a Real-Time Microcontroller 400.20 connected by means of a conductor 2.N1.0 to the first node 2.N1 positioned along the conductor C1.sx.p2_MC1_C2.sx.p1 connecting the first capacitor C1.sx with the third capacitor C2.sx and connected by means of a further conductor 2.N2.0 to the second node 2.N2 positioned along the connecting conductor C2.dx.p2_C3.dx.p1 between the fourth capacitor C2.dx and the fifth capacitor C3.dx; a Digital-Analog Converter 400.30; an user interface 400.40 (keyboard) for entering data, such as for example the transformation ratio “k”; a LCD monitor 400.50; other instruments 400.60.

According to a further embodiment of the method, it is implemented using a first capacitor C1.sx and a second capacitor C1.dx which are two capacitors having a respective dielectric identical to each other and/or a respective dielectric not identical each other (i.e. different) but having the same characteristics in relation to the change in these characteristics if these two capacitors are subjected, over time, to the same functional and environmental vicissitudes (operation, temperature, humidity, etc.) and aging over time.

According to a further embodiment of the method, it is implemented using a fourth capacitor C2.dx which has a capacitance value having the same order of magnitude with respect to the first capacitor C1.sx and/or with respect to the second capacitor C1.dx.

Furthermore, as another embodiment of the method, it is implemented using a first capacitor C1.sx and a second capacitor C1.dx which are two capacitors (two capacities) with a known ratio between them, i.e. two capacitors C1.sx and C1.dx which have a respective capacitance value, Vdc C1.sx and Vdc C1.dx, where these two values have a ratio, . . . C1.sx/C1.dx=known_value . . . , then consider said known_value in the equation/calculation for estimating the voltage relating to the element under voltage ET.

Still preferably, the method also comprises the characteristic of subjecting the first capacitor C1.sx and the second capacitor C1.dx to the same operating and/or exercise and/or environmental and/or aging conditions (under the same vicissitudes) after their installation, i.e. in the subsequent passage of time, such as, for example, providing these two capacitors C1.sx and C1.dx connected and/or assembled and/or positioned and/or placed and/or arranged in such a way as to implement said characteristic.

By way of non-limiting example, these two capacitors C1.sx and C1.dx could be arranged close to each other and/or within the same module, see for example module MA, in such a way that they will both be subjected, during the passage of time, to the same vicissitudes mentioned above.

With reference to the method object of the present invention, see FIGS. 1 and 2, the estimate of the voltage value of the element under voltage ET can be calculated using various methods/equations preferably using the following values: 1) at least one detected voltage value va.sx(t) relating to a first point/node 1.N1/2.N1 positioned along the wire C1.sx.p2_MC1_C2.sx.p1 which connects the first capacitor C1.sx to the third capacitor C2.sx; 2) at least one measured voltage value va.dx(t) relating to a second point/node 1.N2/2.N2 positioned along the conducting wire C2.dx.p2_C3.dx.p1 which connects the fourth capacitor C2.dx to fifth capacitor C3.dx.

### Description System

With reference to FIGS. 1 and 2, the system 300.S/400.S object of the present invention comprises the system 300.S schematically illustrated in FIG. 1 and the system 400.S is schematically illustrated in FIG. 2, in which said two systems 300.S/400.S have common elements specified in the present description with the same references.

This system 300.S/400.S substantially configures a schematic electric circuit 300.10/400.10 which substantially comprises: a first capacitor C1.sx comprising a respective first pole C1.sx.p1 and a second pole C1.Sx.p2; a second capacitor C1.dx comprising a respective first pole C1.dx.p1 and a second pole C1.dx.p2; a third capacitor C2.sx comprising a respective first pole C2.sx.p1 and a second pole C2.sx.p2; a fourth capacitor C2.dx comprising a respective first pole C2.dx.p1 and a second pole C2.dx.p2; a fifth capacitor C3.dx comprising a respective first pole C3.dx.p1 and a second pole C3.dx.p2.

With reference to the components described above and always schematically: the first capacitor C1.sx has its first pole C1.sx.p1 connected to said live element ET; the second capacitor C1.dx has its first pole C1.dx.p1 connected to said live element ET; the third capacitor C2.sx has its first pole C2.sx.p1 connected to the second pole C1.sx.p2 of the first capacitor C1.sx preferably by means of a respective connecting conductor MC1 and its second pole C2.sx.p2 connected to the ground; the fourth capacitor C2.dx has its first pole C2.dx.p1 connected to the functional and environmental vicissitudes (operation, temperature, humidity, etc.) and aging over time.

According to a further embodiment, the fourth capacitor C2.dx has a capacitance value having the same order of magnitude with respect to the first capacitor C1.sx and/or with respect to the second capacitor C1.dx.

Furthermore, as an embodiment variant, for example, the first capacitor C1.sx and the second capacitor C1.dx can be two capacitors (two capacities) with a known relationship between them, i.e. two capacitors C1.sx and C1.dx which have a respective capacitance value, Vdc C1.sx and Vdc_C1.dx, where these two values have a ratio, . . . C1.sx/C1.dx=known_r_value . . . , then consider said known_r_value in the equation/calculation for estimation of the voltage relating to the element under voltage ET.

Always preferably, the system also includes the characteristic of subjecting the first capacitor C1.sx and the second capacitor C1.dx to the same operating and/or exercise and/or environmental and/or aging conditions (under the same vicissitudes) after their installation, i.e. in the subsequent passage of time, such as, for example, providing these two capacitors C1.sx and C1.dx connected and/or assembled and/or positioned and/or placed and/or arranged in such a way as to one or more of these characteristics.

By way of non-limiting example, these two capacitors C1.sx and C1.dx could be arranged close to each other and/or within the same module, for example see module MA, in such a way that they will both be subjected, during the passage of time, to the same vicissitudes mentioned above.

Again with reference to the system object of the present invention, preferably, the third capacitor C2.sx, the fourth capacitor C2.dx and the fifth capacitor C3.dx are three equal and/or identical capacitors.

With reference to FIG. 1, always preferably, the system 300.S can further comprise the following components: a first AC/RMS converter 300.20 connected via a respective conductor 1.N2.0 to the second node 1.N2 positioned along the connection C2.dx.p2_C3.dx.p1 between the fourth capacitor C2.dx and the fifth capacitor C3.dx; a second AC/RSM converter 300.30 connected via a respective conductor 1.N1.0 to the first node 1.N1 positioned along the connecting conductor C1.sx.p2_MC1_C2.sx.p1 between the first capacitor C1.sx and the third capacitor second pole C1.dx.p2 of the second capacitor C1.dx preferably by means of a respective connecting conductor MC2 and its second pole C2.dx.p2 connected to the first pole C3.dx.p1 of the fifth capacitor C3.dx; the fifth capacitor C3.dx has its second pole C3.dx.p2 connected to ground.

With reference to the connections described above, again schematically: the first capacitor C1.sx supplies on the second pole C1.sx.p2 and/or along the respective conducting wire C1.sx.p2_MC1_C2.sx.p1 which connects it to the third capacitor C2.sx, as for example on a first node indicated with 1.N1 in FIG. 1 and with 2.N1 in FIG. 2, a voltage value, va.sx(t), defined here as the first voltage value; the second capacitor C1.dx supplies on its second pole C1.dx.p2 and/or along the respective conducting wire C1.dx.p2_MC2_C2.dx.p1 which connects it to the fourth capacitor C2.dx a voltage value, va.dx(t), defined here as the second voltage value; the third capacitor C2.sx provides on its second pole C2.sx.p2 and along the respective conducting wire which connects it to the ground a voltage value, vb.sx(t), defined here as third voltage value; the fourth capacitor C2.dx supplies on its second pole C2.dx.p2 and/or along the respective conducting wire C2.dx.p2_C3.dx.p1 which connects it to the fifth capacitor C3.dx, as for example on a second node, indicated by 1.N2 in FIG. 1 and indicated by 2.N2 in FIG. 2, a voltage value, vb.dx(t), defined here as the fourth voltage value; the fifth capacitor C3.dx provides on its second pole C3.dx.p2 and along the conducting wire which connects it to the ground a voltage value, vc.dx(t), defined here as the fifth voltage value.

With reference to the system object of the present invention, preferably, the third capacitor C2.sx, the fourth capacitor C2.dx and the fifth capacitor C3.dx are three equal and/or identical capacitors.

With reference to the system object of the present invention, 300.S/400.S, preferably, the first capacitor C1.sx and the second capacitor C1.dx are two equal and/or identical capacitors.

According to a further embodiment of the system, the first capacitor C1.sx and the second capacitor C1.dx are two capacitors having a respective dielectric identical to each other and/or a respective dielectric not identical each other (i.e. different) but in any case having the same characteristics in relation to the change in these characteristics if these two capacitors are subjected, over time, to the same C2.sx; a microcontroller 300.40 connected to said first and second converters 300.20 and 300.30; a display 300.60 connected to said microcontroller 300.40.

With reference to FIG. 2, always preferably, the system 400.S can further comprise the following components: a Real-Time Microcontroller 400.20 connected by means of a conductor 2.N1.0 to the first node 2.N1 positioned along the connection conductor C1.sx.p2_MC1_C2.sx.p1 between the first capacitor C1.sx and the third capacitor C2.sx and connected by means of a respective conductor 2.N2.0 to the second node 2.N2 positioned along the connection conductor C2.dx.p2_C3.dx.p1 between the fourth capacitor C2.dx and the fifth capacitor C3.dx; a Digital-Analog Converter 400.30 connected to said microcontroller 400.20; an user interface (keyboard) 400.40 for entering data, such as for example the transformation ratio “k”, connected to said microcontroller 400.20; a LCD monitor 400.50; other instruments 400.60.

Still with reference to the system object of the present invention, see FIGS. 1/2, system 300.S/400.S, the estimate of the voltage value of the element under voltage ET can be calculated using various methods/equations preferably using the following values: 1) at least one voltage value relating to a first point/node 1.N1/2. N1 positioned along the conducting wire C1.sx.P2_MC1_C2.sx.p1 which connects the first capacitor C1.sx to the third capacitor C2.sx; 2) at least one voltage value relating to a second point/node 1.N2/2.N2 positioned along the conducting wire C2.dx.p2_C3.dx.p1 which connects the fourth capacitor C2.dx to the fifth capacitor C3.dx.

According to a first exemplary embodiment, see FIG. 1, system 300.S, the voltage value of the ET element is calculated using the following equation:

$$Um = Va . sx \cdot Vb . dx / ( Va . sx - Vb . dx ) \qquad ( equation\_ 1 )$$

where:
Um is the RMS value of the voltage relating to said element under voltage ET;
Va.sx=Effective value of the voltage relating to the second pole C1.sx.p2 of the first capacitor C1.sx and/or relating to a first node 1.N1 positioned along the conducting wire C1.sx.P2_MC1_C2.sx.p1 which connects the first capacitor C1.sx to third capacitor C2.sx;
Vb.dx=Effective value of the voltage relating to the second pole C2.dx.p2 of the fourth capacitor C2.dx and/or relating to a second node 1.N2 positioned along the conducting wire C2.dx.p2_C3.dx.p1 which connects the fourth capacitor C2.dx to fifth capacitor C3.dx.

According to a second exemplary embodiment, see FIG. 2, system 400.S, the value voltage of the ET element is calculated using the following equation:

$$um ( t ) = va . sx ( t ) \cdot vb . dx ( t ) / ( va . sx ( t ) - vb . dx ( t ) ) \qquad ( equation\_ 2 )$$

where:
um(t) is the estimated value of the instantaneous primary voltage relating to said element under voltage (ET);
va.sx(t)=Value of the instantaneous voltage relating to the second pole C1.sx.p2 of the first capacitor C1.sx and/or relating to a first node 2.N1 positioned along the conducting wire C1.sx.P2_MC1_C2.sx.p1 which connects the first capacitor C1.sx to the third capacitor C2.sx;
vb.dx(t)=Value of the instantaneous voltage relating to the second pole C2.dx.p2 of the fourth capacitor C2.dx and/or relating to a second node 2.N2 positioned along the conducting wire C2.dx.p2_C3.dx.p1 which connects the fourth capacitor C2.dx to the fifth capacitor C3.dx.

### Modular Structure

With reference to FIGS. 1 and 2, the system 300.S and 400.S can preferably comprise: a first electric module MA; a second electric module MB; first and second connection means MC1 and MC2; wherein the first module MA comprises the first capacitor C1.sx and the second capacitor C1.dx; wherein the second electric module MB comprises the third capacitor C2.sx, the fourth capacitor C2.dx and the fifth capacitor C3.dx; and wherein the first connection means MC1 and MC2 are able to connect said first module MA with respect to said second module MB.

In the exemplary form illustrated in FIG. 1, in the second module MB there is a first node 1.N1, preferably positioned on the first pole C2.sx.p1 of the third capacitor C2.sx, and a relative associated first cable 1.N1.C, in order to transmit the relative signal va.sx(t) preferably outside the module MB and/or to a second ac/rms converter 300.30.

Again in the exemplary form illustrated in FIG. 1, in the second module MB there is also a second node 1.N2, preferably positioned along the connecting wire C2.dx.p2_C3.dx.p1 between the fourth capacitor C2.dx and the fifth capacitor C3.dx, and a related associated second cable 1.N2.C, in order to transmit the related signal va.dx(t) preferably outside the module MB and/or to a first ac/rms converter 300.20.

In the exemplary form illustrated in FIG. 2, in the second module MB there is a first node 2.N1, preferably positioned on the first pole C2.sx.p1 of the third capacitor C2.sx, and a relative associated first cable 2.N1.C, in order to transmit the relative signal va.sx(t) preferably outside the module MB and/or to a Real-Time Microcontroller 400.20.

Again in the exemplary form shown in FIG. 2, in the second module MB there is a second node 2.N2, preferably positioned along the connecting wire C2.dx.p2_C3.dx.p1 between the fourth capacitor C2.dx and the fifth capacitor C3.dx, and a relative associated first cable 2.N2.C, in order to transmit the relative signal va.dx(t) preferably outside the module MB and/or to a Real-Time Microcontroller 400.20.

By means of this technical solution comprising the two modules MA and MB, the first electric module MA can be positioned separately and independently with respect to the positioning of the second electric module MB, the first connection means MC1 connect the second pole C1.sx.p2 of the first capacitor C1.sx with the first pole C2.sx.p1 of said third capacitor C2.sx, and the second connection means MC2 connect the second pole C1.dx.p2 of the second capacitor C1.dx with the first pole C2.dx.p1 of the fourth capacitor C2.dx.

Preferably, said first module MA is positioned in such a way that the first capacitor C1.sx and the second capacitor C1.dx will be subjected over time to the same vicissitudes such as, for example, to the same operating and/or operating conditions, i.e. to same electrical and/or environmental and/or aging and/or other types of conditions.

Again using this modular structure, the first electrical module MA can be positioned in such a way that the first capacitor C1.sx and the second capacitor C1.dx will be subjected over time to the same environmental vicissitudes (temperature, humidity, operation, other, etc.), as for example fixed to the same conductor ET supported on the top of a pylon and therefore subject to the bad weather that will follow one another over time, while the second module MB can be positioned in a more accessible and/or sheltered place, such as for example inside a cabin electric.

### Components

With reference to the first and second embodiments of the system 300.S/400.S, illustrated in the respective FIGS. 1 and 2, as an exemplifying but non-limiting embodiment, the system 300.S/400.S described above could comprise: the first capacitor C1.sx identical with respect to the second capacitor C1.dx and, for example, to use two capacitors manufactured by the company Vishay, product no. 715C30KTT33, having the following characteristics: ceramic capacitor, capacity: 330 pF, ac rated voltage: 20 kV; the third capacitor C2.sx identical to the fourth capacitor C2.dx and identical to the fifth capacitor C3.dx and, for example, to use three capacitors manufactured by the Kemet company, product no. CI206C473JIGACTU, having the following characteristics; ceramic capacitor, capacity: 590 nF, rated voltage 100V, NPO.

In this context, it is specified that the devices C1.sx, C1.dx, C2.sx, C2.dx and C3.dx as specified above by way of example, can also assume other embodiments, capable of performing the same function, without departing from the inventive concepts protected by the present invention, maintaining, preferably, the characteristic of providing the first two capacitors, i.e. the first capacitor C1.sx and second capacitor C1.dx equal and/or identical to each other, as well as, preferably, the other three capacitors, ie the third capacitor C2.sx, the fourth capacitor C2.dx and the fifth capacitor C3.dx equal and/or identical to each other,

With particular reference to the first embodiment illustrated in FIG. 1, the system 300.S could for example use:
as first AC/RMS value converter 300.20, a device capable of converting an alternating voltage waveform into a direct voltage, i.e. capable of calculating (converting) the effective value of an alternating quantity which reaches the input of said first converter device 300.20, such as a commercial converter device known as model AD736 manufactured by Analog Devices;
as second AC/RMS converter 300.30, a converter device identical and/or analogous to the previous first converter 300.20;
as microcontroller 300.40, a device suitable for calculating mathematical formulas, in which said microcontroller 300.40 is always preferably equipped with an analog-digital converter to acquire instantaneous signals, convert them into digital numbers, perform the operations and, therefore, communicate the results to an external display, such as for example a commercial microcontroller known as model PIC24FJ128GC006 manufactured by Microchip Technologies Inc.;
as display 300.60, a device for presenting information, preferably a liquid crystal display of the 4-line type with 20 characters per line, such as for example an LCD-20x4Y commercial display produced by the company Gravitech; as user interface (keyboard), a keyboard or other similar device suitable for allowing data and/or commands to be entered into the aforementioned Microcontroller 300.40. In this context, it is specified that the devices 300.20, 300.30, 300.40, 300.50 and 300.60, as specified above by way of example, can also assume other embodiments, capable of performing the same functions, without departing from the inventive concepts protected by this invention. With particular reference to the second embodiment, illustrated in FIG. 2, the system 400.S could for example to use:
as a Real-Time Microcontroller 400.20, a device capable of calculating formulas and modifying signals acquired with the analog-thimble converter present inside, also having characteristics that allow it to operate with operating systems in real time, such as for example a Real-Time microcontroller known as model DSPIC33FJ16GS402H/MM produced by Microchip Technologies Inc.;
as Digital-Analog Converter 400.30, a Digital-Analog converter device capable of converting a series of data in digital format into an instantaneous-analog signal, such as for example a commercial Digital-Analog Converter known as model DAC121 S101 CIMM/NOPB manufactured by the Texas company Instruments;
as a user interface (keyboard) 400.40, a keyboard or other similar device suitable for allowing data and/or commands to be entered into the aforementioned microcontroller 400.20.

In this context, it is specified that the devices 400.20, 400.30, 400.40, specified above by way of example, can also assume other embodiments, suitable for performing the same functions, without departing from the inventive concepts protected by the present invention.

### Calculation Examples

As an example, with reference to the 300.S system of FIG. 1, using the components as indicated above, i.e.:
as first and second capacitor C1.sx and C1.dx two capacitors manufactured by Vishay company, product no. 715C30KTT33, having the following characteristics: ceramic capacitor, capacity: 330 pF, ac rated voltage: 20 kV;
as third, fourth and fifth capacitors, C2.sx, C2.dx and C3.dx, three capacitors made by Kemet company, product no. C1206C473J1GACTU, having the following characteristics; ceramic capacitor, capacity: 590 nF, rated voltage 100V, NPO.
   and by applying the 300.S system to a live ET element, the following values were detected
at the output of the second converter 300.30 a value Va.sx=5.5682V
at the output of the first converter 300.20 a value Vb.dx=5.5651V
   and, based on the above equation viz

$$Um = Va . sx \cdot Vb . dx / ( Va . sx - Vb . dx ) \qquad ( equation\_ 1 )$$

we'll have

$$Um = 5.5682 V \cdot 5.5651 V / ( 5.5682 V - 5.5651 V )$$

whose result corresponds to

$$Um = 10 kV$$

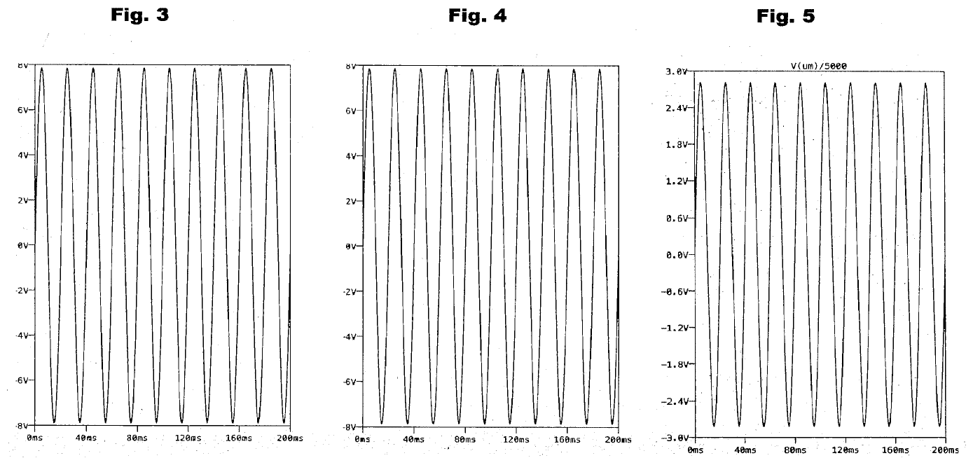

Also by way of example, with reference to the system 400.S of FIG. 2_2A, using the components as indicated above, by applying the system 400.S to a live element ET, the waveforms illustrated in FIG. 3 and in FIG. 4 and, on the basis of the above equation, i.e.

$$um ( t ) = va . sx ( t ) \cdot vb . dx ( t ) \vert ( va . sx ( t ) - vb . dx ( t ) ) \qquad ( equation\_ 2 )$$

the result was the waveform illustrated in FIG. 5.

By means of the method object of the present invention a correct and/or safe estimate of the voltage value of the element under tension is maintained over time, solving the above problems.

By means of the system object of the present invention, a correct and/or safe estimate of the voltage value of the live element is maintained over time, simple and inexpensive maintenance can be performed since the MA module does not require maintenance and the MB module can be positioned in an easily accessible place (such as for example inside an electrical substation) and, therefore, the maintenance and/or repair of said systems, for example in relation to the Module MB, can be performed even if the element subject to measurement is live (for example by equipping the connection means MC1 and MC2 with disconnectors), the repair and maintenance operations can be carried out, for example of the Module MB, by means of non highly specialized workers.

With reference to the above description, the term “module” MA is preferably used to define an independent unit of a complex comprising, for example, two or more modules MA and MB that can be connected together and/or two or more constructively independent units MA and MB connectable each other for example by means of conductors and/or an independent unit MA and other components connectable to said unit MA by means of conductors such as, for example

$$> \_MA + MB + 100.20 + 100.30 + 100.40 + 100.50 + 100 \text{.60} \qquad ( fig . 1 )$$

$$> \_MA + MB + 200.20 + 200.30 + 200.40 + 200.50 + 200.60 \qquad ( fig . 2 )$$

Again preferably, said module MA comprises specific and particular components as above described and, furthermore, said module MA is intended to perform a particular and specific function as part of an apparatus and/or a circuit and/or a complex and/or a system.

Again preferably, said module MA is made as an autonomous self-supporting unit, so that it can be easily removed and/or replaced and/or disconnected with respect to the respective apparatus and/or circuit and/or complex and/or system and, if desirable, said module MA can also provide a shield to protect the related components from the surrounding electric fields.

The description of the system specified above is given purely by way of non-limiting example and, therefore, it is evident that all those modifications or variations suggested by practice and by its use can be made to said system and, in any case, within the scope of scope of the following claims, which also form an integrative part for the present description.

The descriptions of the method and system indicated above are given purely by way of non-limiting example and, therefore, it is evident that all those modifications or variations suggested by practice and by their use can be made to said method and system, however, within the scope of the following claims, which also form an integral part of the present description.

1. A method for of estimating the voltage of a live element of a system comprising:
a first capacitor having a respective first pole and a second pole;
a second capacitor having a respective first pole and a second pole;
a third capacitor having a respective first pole and a second pole;
a fourth capacitor having a respective first pole and a second pole;
a fifth capacitor having a respective first pole and a second pole; wherein
the first capacitor has its first pole connected to the live element,
the second capacitor has its first pole connected to the live element;
the third capacitor has its first pole connected to the second pole of the first capacitor and its second pole connected to ground;
the fourth capacitor has its first pole connected to the second pole of the second capacitor and its second pole connected to the first pole of the fifth capacitor;
the fifth capacitor has its second pole connected to the ground;
the first capacitor and the second capacitor are equal or identical to each other;
the third capacitor, the fourth capacitor and the fifth capacitor are equal or identical to each other;
the first capacitor has on its second pole or along the respective conductor connecting it to the third capacitor a value of electric voltage defined here the first value of electric voltage;
the fourth capacitor has on its second pole or along the respective conductor connecting it to the fifth capacitor a value of electric voltage defined here the fourth value of electric voltage; the method for estimating the voltage of the live element: the method comprising the following steps:
a) detecting at least one value of electric voltage at a first point/node positioned along the conductor that connects the first capacitor to the third capacitor;
b) detecting at least one value of electric voltage at a second point/node positioned along the conductor that connects the fourth capacitor to the fifth capacitor;
c) performing the aforementioned estimate using the voltage at the first point/node detected at the previous step s) and the voltage at the second point/node detected at the detecting step b).

2. The method according to according to claim 1, further comprising the step of;
subjecting the first capacitor and the second capacitor during the passage of time to the same operating or environmental or aging conditions.

3. The method according to according to claim 1, wherein the value of the electrical voltage of the live element is calculated using the following equation:
$$Um = Va . sx \cdot Vb . dx / ( Va . sx - Vb . dx )$$
where
Um=effective value of the voltage of the live element ET;
Va.sx=effective value of the voltage of conductor connecting the first capacitor to the third capacitor;
Vb.dx=effective value of the voltage of the conductor connecting the fourth capacitor to the fifth capacitor.

4. The method according to according to claim 1, wherein the electrical voltage of the live element is calculated using the following equation:
$$um ( t ) = va . sx ( t ) \cdot vb . dx ( t ) / ( va . sx ( t ) - vb . dx ( t ) )$$
where
um (t)=Estimated value of instantaneous primary voltage of the conductor which connecting the first capacitor to the third capacitor;
va.sx (t)=Value of the instantaneous electric voltage of the conductor connecting the first capacitor to the third capacitor;
vb.dx (t)=Value of the instantaneous electric voltage of the conductor that connects the fourth capacitor with the fifth capacitor C3.dx.

5. A system for estimating the voltage of a live element, the system comprising:
a first capacitor having a respective first pole and a second pole;
a second capacitor having a respective first pole and a second pole;
a third capacitor having a respective first pole and a second pole;
a fourth capacitor having a respective first pole and a second pole;
a fifth capacitor having a respective first pole and a second hole; wherein
the first capacitor has its first pole connected to the live element;
the second capacitor has its first pole connected to the live element;
the third capacitor has its first pole connected to the second pole of the first capacitor and its second pole connected to ground;
the fourth capacitor has its first pole connected to the second pole of the second capacitor and its second pole connected to the first pole of the fifth capacitor;
the fifth capacitor has its second pole connected to the ground;
the first capacitor and the second capacitor are equal or identical to each other;
the third capacitor, the fourth capacitor and the fifth capacitor are equal or identical to each other;
the first capacitor has on its second pole or along the respective conductor connecting it to the third capacitor a value of electric voltage defined here the first value of electric voltage;
the fourth capacitor has on its second pole or along the respective conductor connecting it to the fifth capacitor a value of electric voltage defined here the fourth value of electric voltage,
the first capacitor has on its second pole or along the respective conductor connecting it to the third capacitor a value of electric voltage defined here the first value of electric voltage; and
the fourth capacitor has on its second pole or along the respective conductor connecting it to the fifth capacitor a value of electric voltage defined here the fourth value of electric voltage.

6. The system according to claim 5, wherein the first capacitor and the second capacitor are connected or are positioned or are placed or are arranged in such a way as to be subjected over the course of time to the same operating or environmental or aging conditions.

7. The system according to claim 5, wherein the system is configured to estimate the value of the electrical voltage of the live element using the following values:
at least one voltage of the voltage regarding a first point/node positioned along the conductor connecting the first capacitor to the third capacitor; and
at least one voltage regarding a second point/node positioned along the conductor connecting the fourth capacitor to the fifth capacitor.

8. The system according to claim 5, further comprising:
a first AC/RMS converter;
a second AC/RSM converter; and
a microcontroller.

9. The system according to according to claim 5, wherein the system is configured to estimate the value of the electrical voltage of the live element using the following equation:
$$Um = Va . sx \cdot Vb . dx / ( Va . sx - Vb . dx )$$
where
Um=effective value of the voltage of the live element ET;
0Va.sx=effective value of the voltage regarding the second pole of the first capacitor or regarding a first node positioned along the conductor connecting the first capacitor to the third capacitor;
Vb.dx=effective value of the voltage regarding the second pole of the fourth capacitor or regarding a second node positioned along the conductor connecting the fourth capacitor to the fifth capacitor.

10. The system according to according to claim 5, wherein it further comprises:
a Microcontroller Real-Time; and
a Digital-Analog Converter connected to the microcontroller.

11. The system according to claim 5, wherein the system is configured to estimate the value of the electrical voltage of the live element using the following equation:
$$um ( t ) = \frac{va . sx ( t ) vb . dx ( t )}{( va . sx ( t ) - vb . dx ( t ) )}$$
where
um (t)=Estimated value of instantaneous primary voltage of the live element;
va.sx (t)=Value of the instantaneous electric voltage regarding the second pole of the first capacitor or regarding a first node positioned along the conductor connecting the first capacitor to the third capacitor;
vb.dx (t)=Value of the instantaneous electric voltage regarding the second pole of the fourth capacitor or regarding a second node positioned along the conductor that connects the fourth capacitor with the fifth capacitor C3.dx.

12. The system according to claim 5, further comprising:
a first module;
a second module;
first means of connection;
second means of connection; wherein
the first module comprises has the first capacitor and the second capacitor;
the second module has the third capacitor, the fourth capacitor and the fifth capacitor;
the first module is positioned separately and independently with respect to the positioning of the second module;
the first connection means connect the second pole of the first capacitor with the first pole of the third capacitor;
the second connection means connect the second pole of the second capacitor with the first pole of fourth capacitor.

13. The system according to claim 12, wherein the first module is positioned in such a way that the first capacitor and the second capacitor will be subjected to the same functional or environmental or aging vicissitudes.
